(19) United States
(12) Patent Application Publication
(10) Pub. No.: US 2008/0124934 A1
(43) Pub. Date: May 29, 2008

(54) Method of manufacturing a semiconductor device

(75) Inventor: Cheon-Bae Kim, Anyang-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/812,137

(22) Filed: Jun. 15, 2007

(30) Foreign Application Priority Data
Jun. 26, 2006 (KR) 10-2006-0057447

(51) Int. Cl. H01L 21/71

(52) U.S. Cl. 438/699; 257/E21.536

(57) ABSTRACT

In one embodiment, a preliminary insulation layer is formed over a cell region and a peripheral circuit region of a semiconductor substrate. The preliminary insulation layer covers a capacitor formed over the cell region. The preliminary insulation layer over the cell region has a first height higher than a second height of the preliminary insulation layer over the peripheral circuit region. A preliminary node separate polymer layer is formed over the preliminary insulation layer. A portion of the preliminary node separate polymer layer is uniformly removed by a developing process to form a node separate polymer layer exposing the preliminary insulation layer over the cell region. A portion of the preliminary insulation layer over the cell region is removed to form an insulation layer.

### PRIORITY STATEMENT

This application claims priority under 35 USC § 119 to Korean Patent Application No. 2006-57447 filed on Jun. 26, 2006, the contents of which are herein incorporated by reference in their entirety.

### BACKGROUND

1. Field

Example embodiments of the present invention relate to a method of manufacturing a semiconductor device.

2. Description of the Related Art

In case of a conventional method of manufacturing a semiconductor memory device such as a dynamic random access memory (DRAM) device, a step height between a cell region and a peripheral circuit region is produced because a capacitor is only formed on the cell region, but not on the peripheral circuit region.

Recently, a dimension of a memory cell, which stores 1 bit as a basic unit of memory information, has been decreased as an integration degree of the semiconductor device increases. This result in part because of a current trend to downsize a size of a pattern applied to product manufacturing in order to increase a number of chips that may be formed per a wafer. However, the degree to which the area of a capacitor may be shrunk in proportion to a reduction in a size of a memory cell is limited by a need to prevent soft errors and maintain stability.

One of the methods to ensure enough capacitance in the limitedly shrunk area of the capacitor is to form a three-dimensionally structured capacitor, to thereby effectively increase overall surface area of a capacitor electrode. That is, to increase a capacitance of a capacitor, it is necessary to increase a surface area between two electrodes. However, the area of a capacitor is shrunk to meet the trend of reducing a size of a chip as described above. As a result, a height of the capacitor has been increased.

FIGS. 1A and 1B are cross-sectional views illustrating a conventional method of manufacturing a semiconductor device.

Referring to FIGS. 1A and 1B, a step height between a cell region and a peripheral circuit region is formed. In particular, a capacitor 11 is formed only on the cell region, but not on the peripheral circuit region of a semiconductor substrate 10. FIG. 1A is a cross-sectional view illustrating an insulation layer 12 deposited on the cell region and the peripheral circuit region, and FIG. 1B illustrates that the step height difference between the cell and peripheral regions remain. Also, metal residues may still remain because of the step height after a deposition process, thereby causing a bridge between the metal lines.

In a conventional planarization process, which removes a step height between the cell region and the peripheral circuit region after forming the capacitor 11 above a bit line, an interlayer dielectric layer is etched using a reticle by a photolithography process to open the cell region. As a result, in the conventional planarization process, various defects are generated by an align miss and a broken pillar caused by mechanical stress during a chemical mechanical polishing process.

### SUMMARY

Example embodiments of the present invention provide a method of manufacturing a semiconductor device. At least one advantage of the method provides for removing a step height between a cell region and a peripheral circuit region of a semiconductor substrate.

In one embodiment, a preliminary insulation layer is formed over a cell region and a peripheral circuit region of a semiconductor substrate. The preliminary insulation layer covers a capacitor formed over the cell region. The preliminary insulation layer over the cell region has a first height higher than a second height of the preliminary insulation layer over the peripheral circuit region. A preliminary node separate polymer layer is formed over the preliminary insulation layer. A portion of the preliminary node separate polymer layer is uniformly removed by a developing process to form a node separate polymer layer that exposes the preliminary insulation layer over the cell region. A portion of the preliminary insulation layer over the cell region is removed to form an insulation layer.

In an example embodiment, the preliminary insulation layer may be formed using undoped silicate glass (USG), high temperature oxide (HTO), medium temperature oxide (MTO), tetra-ethyl-ortho-silicate (TEOS), high density plasma (HDP) oxide, boro-phospho-silicate glass (BPSG), phospho-silicate glass (PSG), boro-silicate glass (BSG), etc. The preliminary insulation layer may have a multi-layered structure.

The preliminary node separate polymer may be uniformly removed by performing an exposing process and a developing process.

The method of manufacturing a semiconductor device further includes removing the node separate polymer layer arranged on the peripheral circuit region, and performing a planarization process on the preliminary insulation layer after removing the node separate polymer layer. The node separate polymer layer may be removed by performing an ashing process and/or a stripping process.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

The above and other features and advantages of the present invention will become more apparent by describing in detailed example embodiments thereof with reference to the accompanying drawings, in which:

FIGS. 1A and 1B are cross-sectional views illustrating a conventional method of manufacturing a semiconductor device.

FIGS. 2 to 6 are cross-sectional views illustrating a method of manufacturing a semiconductor device according to a first example embodiment of the present invention.

FIGS. 7 to 11 are cross-sectional views illustrating a method of manufacturing a semiconductor device according to a second example embodiment of the present invention.

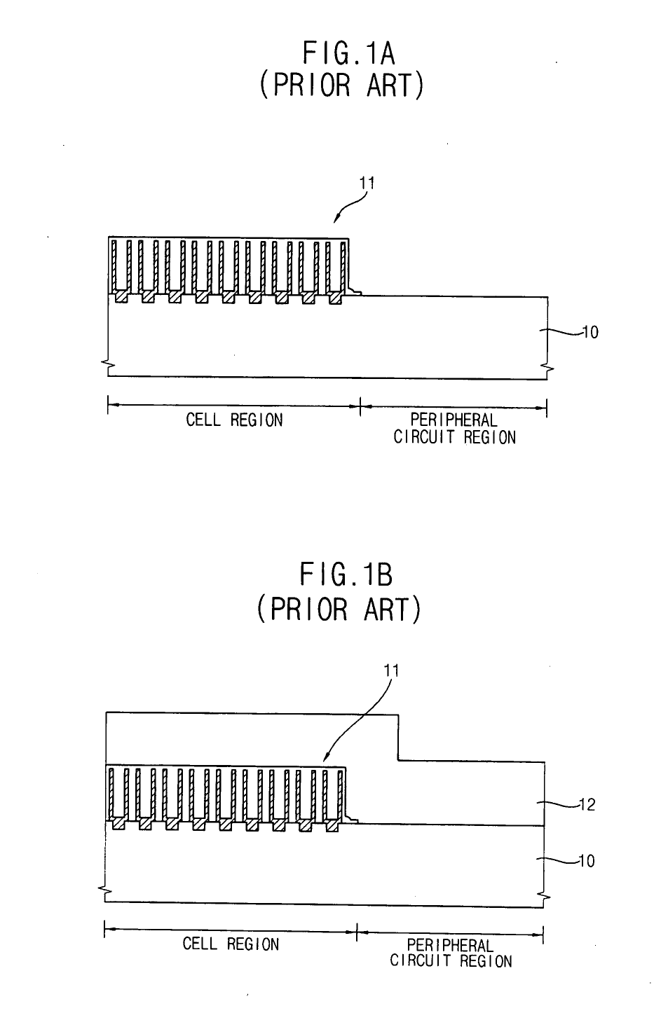

### DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like reference numerals refer to like elements throughout the description of the figures. It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### Example Embodiment 1

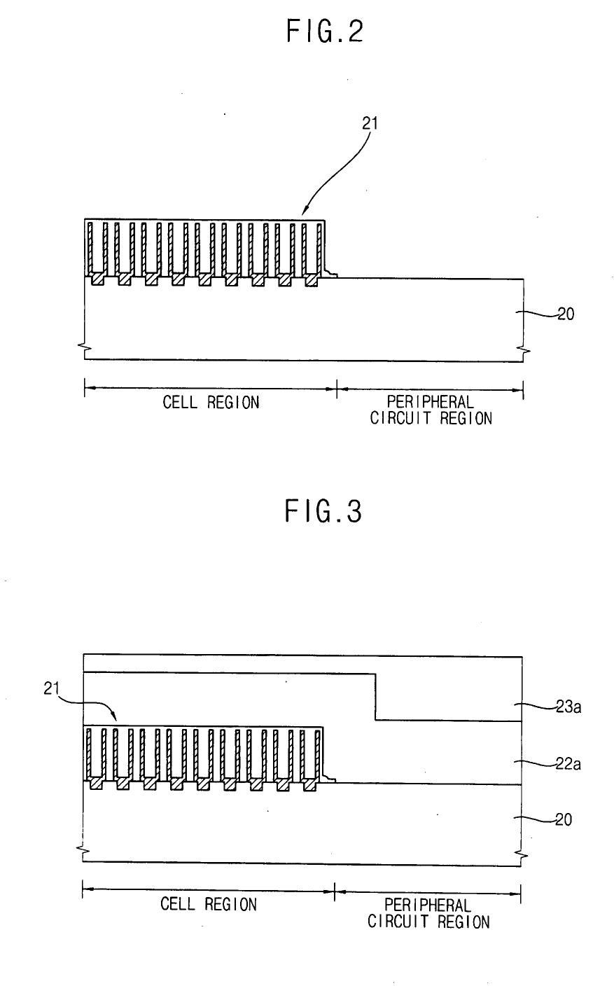

FIGS. 2 to 6 are cross-sectional views illustrating a method of manufacturing a semiconductor device according to a first example embodiment of the present invention.

Referring to FIG. 2, at least one capacitor 21 is formed in a cell region of a semiconductor substrate 20, which includes the cell region and a peripheral circuit region. Although not illustrated in detail, the semiconductor substrate 20 may include at least one transistor electrically connected to the capacitor 21. The transistor may include a source region, a drain region, a channel region, a gate oxide layer and a gate electrode. For example, the channel region may be arranged between the source region and the drain region. The gate electrode may be arranged on the gate oxide layer. The source region and the drain region may be doped with impurities by an ion implantation process. The semiconductor substrate 20 may include at least one contact and at least one wiring.

The capacitor 21 may have substantially a cylindrical shape. Further, the capacitor 21 may include an upper electrode, a dielectric layer and a lower electrode. The capacitor 21 may further include an insulating structure that is formed on the cell region to cover the upper electrode.

Referring to FIG. 3, a preliminary insulation layer 22a is formed on the semiconductor substrate 20 to cover the capacitor 21 and the peripheral circuit region. The capacitor 21 is formed only on the cell region as described above. Therefore, the preliminary insulation layer 22a on the cell region has a first height substantially higher than a second height of the preliminary insulation layer 22a on the peripheral circuit region. The preliminary insulation layer 22a may be formed using an oxide, which does not include impurities, such as undoped silicate glass (USG), high temperature oxide (HTO), medium temperature oxide (MTO), tetra-ethyl-ortho-silicate (TEOS), high density plasma (HDP) oxide, etc. These materials may be used alone or in a combination as the preliminary insulation layer 22a. Alternatively, the preliminary insulation layer 22a may be formed using an oxide, which includes impurities, such as boro-phospho-silicate glass (BPSG), phospho-silicate glass (PSG), boro-silicate glass (BSG), and so on. These materials may be used alone or in a combination as the preliminary insulation layer 22a. As illustrated in FIG. 3, the preliminary insulation layer 22a may have a single-layered structure. Alternatively, the preliminary insulation layer 22a may have a multi-layered structure.

A preliminary node separate polymer (NSP) layer 23a is formed to have a thickness of about 20,000 Å to about 30,000 Å on the preliminary insulation layer 22a. Forming the preliminary NSP layer 23a in this thickness range results in the preliminary NSP layer 23a smoothing the step height of the preliminary insulation layer 22a between the cell region and the peripheral region.

When a conventional photoresist material is used instead of the preliminary node separate polymer layer 23a in order to form a photoresist film, it is difficult to control a thickness of the photoresist film due to partial unevenness of the photoresist film. However, when sequentially performing an exposing process and a developing process on the preliminary node separate polymer layer 23a, the preliminary node separate polymer layer 23a may be removed from the upper portion thereof at a relatively uniform speed. Thus, a processing time of the developing process may be readily controlled, thereby effectively controlling a height of the preliminary node separate polymer layer 23a.

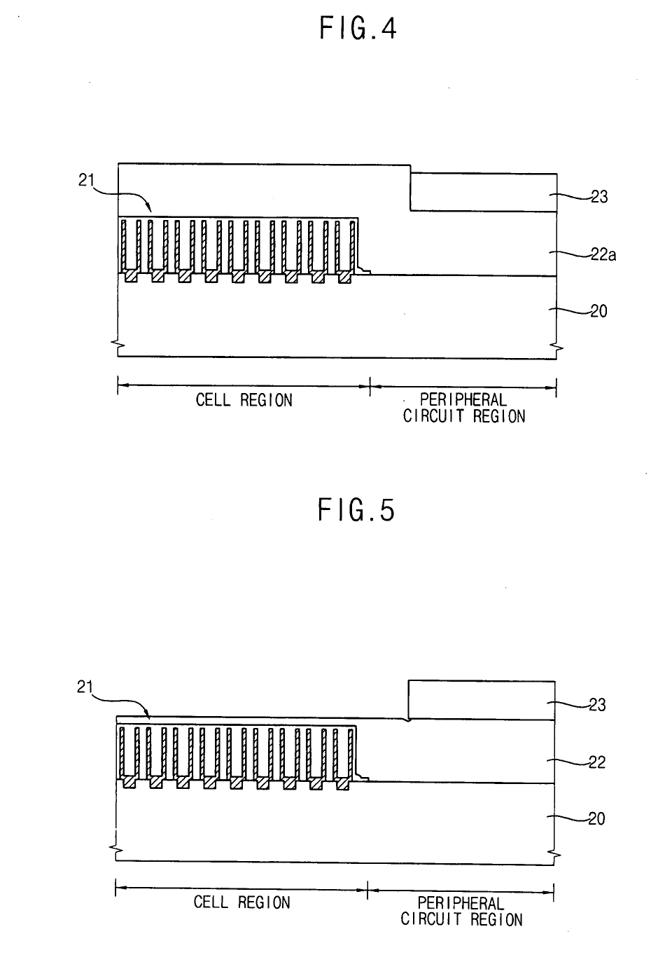

Referring to FIG. 4, the preliminary node separate polymer layer 23a is formed on the preliminary insulation layer 22a. Then, after performing an exposing process on the preliminary node separate polymer layer 23a, a portion of the preliminary insulation layer 22a on the cell region is exposed through a developing process. Here, the preliminary node separate polymer layer 23a is removed uniformly from the upper portion during the developing process to effectively expose a portion of the preliminary insulation layer 22a over the cell region. Accordingly, a portion of the preliminary node separate polymer layer 23a on the cell region is completely removed and a portion of the preliminary node separate polymer layer 23a on the peripheral circuit region is partially removed to have a desired (or, alternatively, a predetermined) height by controlling a time of the developing process. This thereby exposes a portion of the preliminary insulation layer 22a on the cell region. As a result, the preliminary node separate polymer layer 23a is transformed into a node separate polymer layer 23 arranged on the peripheral circuit region.

Referring to FIG. 5, the preliminary insulation layer 22a is etched using the remaining node separate polymer layer 23 as a mask after performing the developing process. The etching process may include a dry etching process or a wet etching process. The dry etching process may be an isotropic dry etching process or an anisotropic dry etching process. A portion of the preliminary insulation layer 22a arranged over the cell region is removed by the etching process. The preliminary insulation layer 22 having a step height is transformed into an insulation layer 22 having a substantially planar surface. A wet etching solution used for removing the portion of the preliminary insulation layer 22a arranged over the cell region during the etching process may be a hydrofluoric acid (HF) solution or a buffered oxide etchant. These materials may be used alone or in a combination as the etchant. Furthermore, it will be appreciated that the etchant used has etch selectivity with respect to the node separate layer pattern 23.

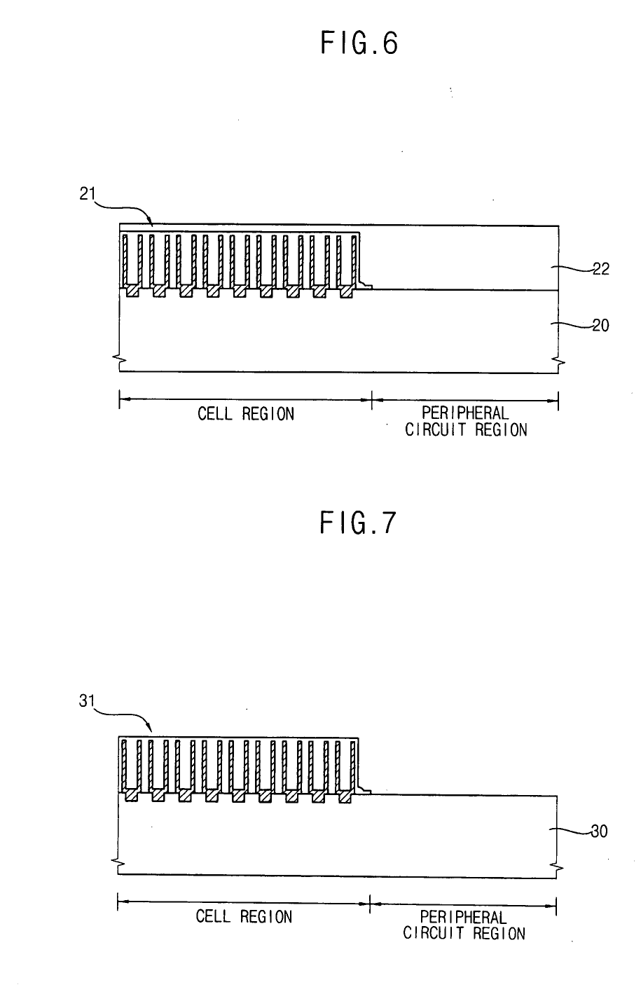

Referring to FIG. 6, the node separate polymer layer 23 is removed. The node separate polymer layer 23 may be removed using an ashing process and/or a stripping process. These techniques may be used alone or in a combination to remove the node separate polymer layer 23.

According to this example embodiment, the node separate polymer layer 23 may be adopted to simplify a planarization process. A height of the node separate polymer layer 23 is uniformly decreased by controlling a time of a developing process after performing an exposing process, so that a reticle is not required and the resulting pattern is self-aligned. In addition, a following chemical mechanical polishing (CMP) process may be relatively easily performed, to thereby improve problems such as a misalignment and a broken pillar caused by a mechanical stress during the CMP process.

### Example Embodiment 2

FIGS. 7 to 11 are cross-sectional views illustrating a method of manufacturing a semiconductor device according to a second example embodiment of the present invention.

Referring to FIG. 7, at least one capacitor 31 is formed on a cell region of a semiconductor substrate 30, which includes the cell region and a peripheral circuit region. Although not illustrated in detail, the semiconductor substrate 30 may include at least one transistor electrically connected to the capacitor 31. The transistor may include a source region, a drain region, a channel region, a gate oxide layer and a gate electrode. For example, the channel region may be arranged between the source region and the drain region. The gate electrode may be arranged on the gate oxide layer. The source region and the drain region may be doped with impurities by an ion implantation process. Also, the semiconductor substrate 30 may include at least one contact and at least one wiring.

The capacitor 31 may have a substantially cylindrical shape. Further, the capacitor 31 may include an upper electrode, a dielectric layer and a lower electrode. The capacitor 31 may further include an insulating structure that is formed on the cell region to cover the upper electrode.

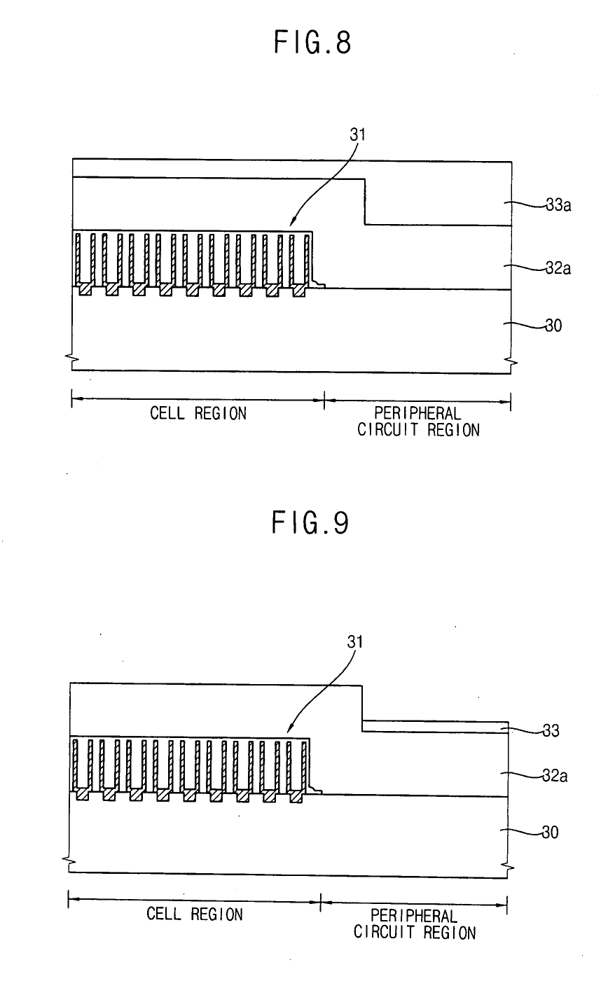

Referring to FIG. 8, a preliminary insulation layer 32a is formed on the semiconductor substrate 30 to cover the capacitor 31 formed only on the cell region. Therefore, the preliminary insulation layer 32a on the cell region has a first height higher than a second height of the preliminary insulation layer 32a on the peripheral circuit region. The preliminary insulation layer 32a may be formed using an oxide, which does not include impurities, such as undoped silicate glass (USG), high temperature oxide (HTO), medium temperature oxide (MTO), tetra-ethyl-ortho-silicate (TEOS), high density plasma (HDP) oxide, and so on. These materials may be used alone or in a combination as the preliminary insulation layer 32a. Alternatively, the preliminary insulation layer 32a may be formed using an oxide, which includes impurities, such as a boro-phospho-silicate glass (BPSG), a phospho-silicate glass (PSG), a boro-silicate glass (BSG), and so on. These materials may be used alone or in a combination as the preliminary insulation layer 32a. As illustrated in FIG. 8, the preliminary insulation layer 32a may have a single-layered structure. Alternatively, the preliminary insulation layer 32a may have a multi-layered structure. Then, a preliminary node separate polymer layer 33a is formed on the preliminary insulation layer 32a.

Referring to FIG. 9, the preliminary node separate polymer layer 33a is formed to cover the capacitor and the peripheral circuit region, and an exposing process is performed on the preliminary node separate polymer layer 33a. Then, a developing process is performed on the preliminary node separated polymer layer 33a to expose a portion of the preliminary insulation layer 32a on the cell region. Thus, the preliminary node separate polymer layer 33a is transformed into a node separate polymer layer 33 arranged only on the peripheral region. According to another example embodiment, a height of the node separate polymer layer 33 may be substantially lower that of the node separate polymer layer 23 illustrated in FIG. 4. By increasing a time for a developing process to form the node separate polymer layer 33, the node separate polymer layer 33 illustrated in FIG. 9 may be formed to have a height substantially lower than that of the node separate polymer layer 23 illustrated in FIG. 4.

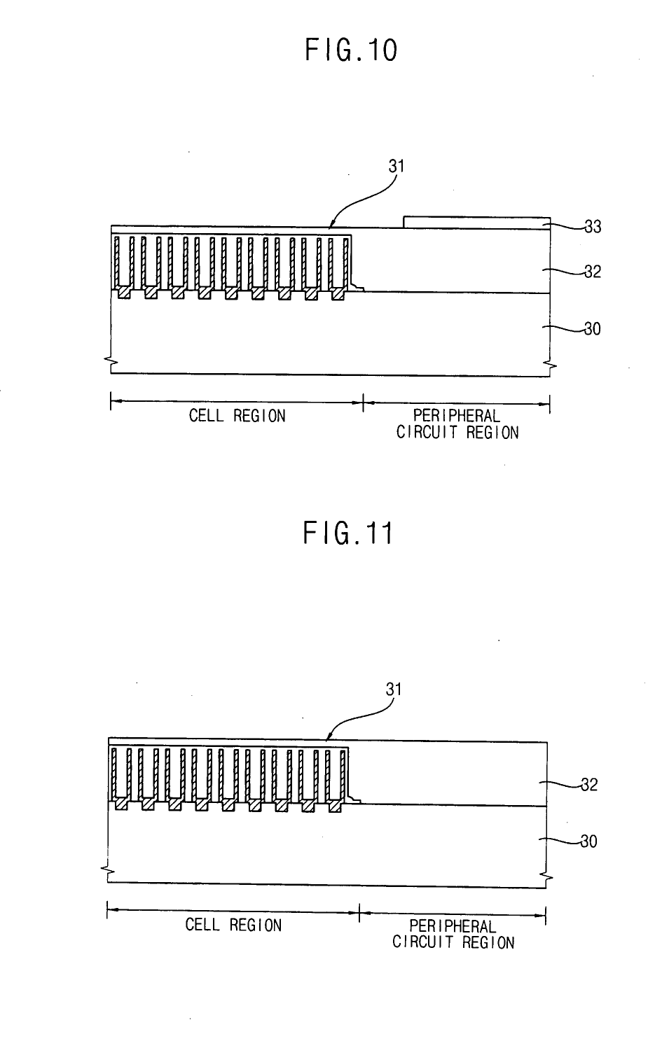

Referring to FIG. 10, the preliminary insulation layer 32a is etched using the node separate polymer layer 33 as an etching mask. The etching process may include a dry etching process or a wet etching process. The dry etching process may be an isotropic dry etching process or an anisotropic dry etching process. A portion of the preliminary insulation layer 32a arranged over the cell region is removed by the etching process. The preliminary insulation layer 32a having a step height is transformed into an insulation layer 32 having a substantially planar surface.

Referring to FIG. 11, after forming the insulation layer 32, the node separate polymer layer 33 remaining on the insulation layer 32 over the peripheral circuit region may be removed using an ashing process and/or a stripping process. These techniques may be used alone or in a combination. According to second example embodiment, the node separate layer pattern 33 is adopted to simplify a planarization process. A height of the node separate layer pattern 33 is uniformly decreased by controlling a time of a developing process after performing an exposing process, so that a reticle may not be required and the resulting pattern is self-aligned. In addition, a following chemical mechanical polishing (CMP) process may be relatively easily performed, to thereby improve problems such as a misalignment and a broken pillar caused by a mechanical stress during the CMP process.

According to the present invention, the step height between the cell region and the peripheral circuit region of the substrate may be removed effectively. As a result, a following process may be performed effectively to improve a process throughput and a reliability of a device.

The foregoing is illustrative and is not to be construed as limiting thereof. Although a few example embodiments have been described, those skilled in the art will readily appreciate that many modifications are possible in the example embodiments without materially departing from the novel teachings and advantages of the embodiments. Accordingly, all such modifications are intended to be included within the scope of the present invention.

What is claimed is:

1. A method of manufacturing a semiconductor device, comprising:
forming a preliminary insulation layer over a cell region and a peripheral circuit region of a semiconductor substrate, the preliminary insulation layer covering a capacitor formed over the cell region, the preliminary insulation layer over the cell region having a first height higher than a second height of the preliminary insulation layer over the peripheral circuit region;
forming a preliminary node separate polymer layer over the preliminary insulation layer;
uniformly removing a portion of the preliminary node separate polymer layer by a developing process to form a node separate polymer layer exposing the preliminary insulation layer over the cell region; and
removing a portion of the preliminary insulation layer over the cell region to form an insulation layer.

2. The method of claim 1, further comprising:
removing the node separate polymer layer over the peripheral circuit region.

3. The method of claim 2, wherein, after the removing the node separate polymer layer over the peripheral circuit region step, further comprising:
performing a planarization process on the preliminary insulation layer.

4. The method of claim 2, wherein the node separate polymer layer over the peripheral circuit is removed by performing at least one of an ashing process and a stripping process.

5. The method of claim 1, wherein the removing a portion of the preliminary insulation layer step includes performing at least one of a dry etching process and a wet etching process.

6. The method of claim 5, wherein the dry etching process includes at least one of an isotropic dry etching process and an anisotropic dry etching process.

7. The method of claim 1, wherein the preliminary insulation layer is formed using at least one selected from the group consisting of undoped silicate glass (USG), high temperature oxide (HTO), medium temperature oxide (MTO), tetra-ethyl-ortho-silicate (TEOS), high density plasma (HDP) oxide, boro-phospho-silicate glass (BPSG), phospho-silicate glass (PSG), and boro-silicate glass (BSG).

8. The method of claim 7, wherein the preliminary insulation layer has a multi-layered structure.

9. The method of claim 1, wherein uniformly removing a portion of the preliminary node separate polymer layer includes performing an exposing process and then the developing process.

10. The method of claim 9, wherein uniformly removing a portion of the preliminary node separate polymer layer uniformly removes an upper portion of the preliminary node separate polymer layer.

11. The method of claim 1, wherein forming a preliminary node separate polymer layer forms the preliminary node separate polymer layer to a thickness of 20,000 to 30,000 Å.
